(19) United States
(12) Patent Application Publication
(10) Pub. No.: US 2006/0048701 A1
(43) Pub. Date: Mar. 9, 2006

(54) Method of growing group III nitride crystals

(76) Inventors: Boris N. Feigelson, Springfield, VA (US); Richard L. Henry, Great Falls, VA (US)

Correspondence Address: NAVAL RESEARCH LABORATORY;ASSOCIATE COUNSEL (PATENTS), CODE 1008.2, 4555 OVERLOOK AVENUE, S.W., WASHINGTON, DC, 20375-5320, US

(21) Appl. No.: 11/217,854

(22) Filed: Sep. 1, 2005

Related U.S. Application Data
(60) Provisional application No. 60/610,866, filed on Sep. 3, 2004.

(51) Int. Cl. C30B 23/00; C30B 28/12; C30B 28/14; C30B 25/00

(52) U.S. Cl. 117/89; 117/84

(57) ABSTRACT

In one embodiment, this invention pertains to a process for making single crystal gallium nitride in the region of the phase diagram of gallium nitride where gallium nitride is thermodynamically stable. The process includes the steps of placing a charged reaction vessel into a chamber, the reaction vessel containing a gallium nitride source and a salt-based solvent in contact therewith; heating the charge in the reaction vessel to render the solvent molten and to provide a temperature gradient in the molten solvent between the gallium nitride source and the growing single crystal gallium nitride in such a way that growing the single crystal gallium nitride will be in the region of the reaction vessel which, under operating conditions, will have a temperature near the low end of the temperature gradient and the gallium nitride source will be in the region of the reaction vessel which, under operating conditions, will have temperature near the high end of the temperature gradient; maintaining process conditions whereby the solvent is molten, with the gallium nitride from the gallium nitride source dissolving in the solvent under the impetus of the temperature gradient; precipitating gallium nitride out of the solvent; and discontinuing the heating step.

### CROSS-REFERENCE TO RELATED APPLICATION

This patent application claims the benefit of U.S. Provisional Patent Application No. 60/610,866 filed Sept. 3, 2004, with the same title.

### BACKGROUND OF THE INVENTION

1. Field of the Invention

This invention is characterized by low temperature and low pressure preparation of single crystal Group III of the Periodic Tabel nitride with a temperature gradient.

2. Description of Related Art

Group III single crystal nitrides have a wide bandgap, with gallium nitride having a bandgap of 3.4 eV at 300 K whereas silica has a bandgap of about 1 at the same temperature. Semiconductor light emitting devices using gallium nitride (GaN) semiconductors, and other Group III nitrides, are theoretically capable of emitting light over a wide range from visible spectrum to the ultraviolet. Because of such characteristics, the gallium nitride semiconductors, particularly gallium nitride, have been placed under active development during the last 15 years or so. Group III nitride semiconductors, particularly gallium nitride semiconductors, also have a large possibility as a material of high electron mobility devices and have been expected to be used as material of high frequency and high-power semiconductor devices.

For manufacturing light emitting or electronic devices using such nitride semiconductors, it is necessary to grow the nitride semiconductor by chemical vapor deposition or molecular beam epitaxy. The best substrate for these processes should be single crystal Group III nitride, particularly gallium nitride. If a wide bandgap Group III nitride single crystal substrate were obtained, the problem of the mismatches of the lattice constant and the thermal expansion would be entirely solved.

One of the techniques presently used for commercial production of gallium nitride substrates is hydride vapor-phase epitaxy, which has been used to grow wafers up to about 2 inches in diameter at growth rates of over 100 μm/hr. The dislocation density of the best of such samples is approximately 10⁶/cm². The known technique for single-crystal growth involves deposition of gallium nitride from a liquid phase. Growth from the liquid phase has resulted in gallium nitride single crystals with dislocation densities of less than 10²/cm². Some of the liquid phase techniques are done using high pressures and high temperatures. High nitrogen pressure counters the gallium nitride decomposition that occurs at the high temperatures of above 1500° C. required to dissolve nitrogen in gallium. These high pressure high temperature/high techniques have been used to grow gallium nitride crystal platelets of up to 1.5 cm in lateral size. Since the crystal growth here requires pressures on the order of 10 kbar and the rates of crystal growth are low, the routine growth of 2 inches in diameter wafers on a production scale is a daunting challenge.

Gallium nitride has also been grown at lower temperatures/pressures by a sodium flux method and by a lithium flux method. Both flux methods use elemental gallium, gaseous nitrogen and either elemental alkali metal or alkali metal nitrides to increase reactivity and solubility of nitrogen in gallium. In the sodium flux and the lithium flux methods, the gaseous nitrogen reacts with the flux/elemental gallium to saturate the solution and deposit crystals. For both of these flux technologies, it has been difficult to establish and control seeded growth of large gallium nitride crystals because the composition of the melt is not well controlled.

It is also well known that gallium nitride crystals can be prepared by flowing ammonia and nitrogen over a gallium melt to increase dissolution of nitrogen in gallium at atmospheric pressure at 850° C. to 1000° C.

All of the more current methods include the feature of nitrogen dissolution in the melt from a gaseous nitrogen source and the reaction of nitrogen and gallium. If a complex flux of gallium and another component is used, the composition of the solution changes during the growth of gallium nitride because of gallium nitride consuming and this makes difficult to control crystal growth.

An important feature in gallium nitride growth, generally, is control over the numerous variables, such as gas pressure, temperature, phase changes, and other phenomena involved in the reaction. Where some of these variables can be combined, excluded or minimized, a greater degree of control over the remainder may be exercised on order to predetermine certain characteristics of the final gallium nitride crystals. Control over the actual growth of a gallium nitride crystals permits growth of larger crystals or of obtaining crystals of various shapes and sizes. Such control can also provide means to predetermine crystal purity, structure perfection and semiconductor properties.

### OBJECTS AND BRIEF SUMMARY OF THE INVENTION

It is an object of this invention to provide improved control over Group III nitride, particularly gallium nitrride, single crystal growth.

It is another object of this invention to prepare single crystal gallium nitride, and other nitrides, at lower temperature and low pressure.

It is another object of this invention to use molten salt-based solvent in a process characterized by a temperature gradient or a temperature differance.

It is another object of this invention to grow single crystal gallium nitride in a molten solvent that is free of gallium.

It is another object of this invention to grow single crystal gallium nitride in absence of nitrogen dissolution in order to react gallium with nitrogen to grow the gallium nitride crystals.

It is another object of this invention to grow single crystal gallium nitride of a large size exceeding about one inch.

It is another object of this invention to grow single crystal gallium nitride at a growth rate exceeding prior art.

It is another object of this invention to grow commercial size and commercial grade single crystal gallium nitride, and other Group III nitrides, for use in electronic devices.

It is another object of this invention to grow single crystal gallium nitride, and other Group III nitrides, by a low temperature and low pressure process with a dislocation density in the crystals of fewer than about 100 dislocations per square centimeter.

These and other objects of this invention can be accomplished by a process of growing single crystal gallium nitride, and other Group III nitrides, at nitrogen pressure and temperature in the region of the phase diagram where the gallium nitride is thermodynamically stable, which process includes using a solid Group III nitride as a source for growing the nitride crystals and using a Group III element-free solvent for the nitride. In such a way, it is possible to eliminate dissolution of gaseous nitrogen in a liquid, reaction of nitrogen with the Group III element, and a change of the solutions's composition during the growth of the nitride.

In practice, this invention includes the steps of selecting components for a reaction vessel to provide a predetermined temperature difference under operating conditions; assembling these components and enclosing a charge therein. This charge comprises (1) a source of Group III nitride located in a region of the reaction vessel which, under operating conditions, will have a temperature at or near the high end of the temperature differencet, and (2) a salt-based solvent catalyst in contact with the source of the Group III nitride, the solvent catalyst being prepared from the alkali metal nitride combined with metal halides or metal fluorides, or their combinations, which may also include at least one nitride seed crystal located in the reaction vessel in the region of the reaction vessel which, under operating conditions, will have a temperature at or near the low end of the aforementioned temperature gradient/difference. The process includes simultaneously subjecting the reaction vessel and the charge therein both to pressure and temperature in the Group III nitride stable region of the phase diagram of the nitride and to heating, at a temperature in excess of the melting point of the solvent, whereby the nitride is first dissolved in a molten solvent catalyst in the hotter part of the reaction vessel and then precipitating from the molten solution to grow single crystals either self-seeded or on a seed, if one was included, in the cooler part of the reaction vessel.

### BRIEF DESCRIPTION OF THE DRAWINGS

FIG. 1 shows reaction vessel or growth chamber where single crystal Group III nitride product is made under a nitrogen atmosphere.

FIG. 2 shows the Raman spectrum of single crystal gallium nitride, which is of wurtzite type with good crystallinity.

FIG. 3 illustrates thermodynamic equilibrium curve for single crystal gallium nitride wherein above the curve, the gallium nitride is stable and does not dissociate into gallium and nitrogen, as it does below the curve.

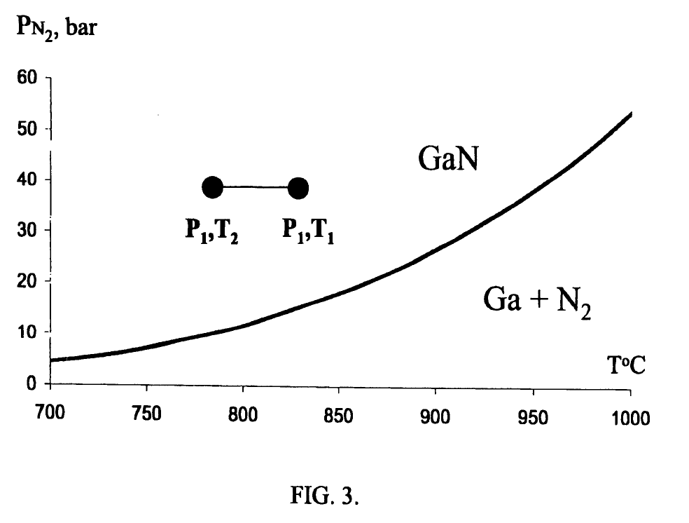

FIGS. 4(A) and (B) show rod-shaped single crystal gallium nitride product made by the low temperature and low pressure temperature gradient process disclosed herein.

### DETAILED DESCRIPTION OF THE INVENTION

This invention pertains to a process for growing single crystal Group III nitride, particularly gallium nitride, which process is characterized by the use of a molten salt-based solvent that does not contain Group III element in the solvent and the application of a temperature gradient to control dissolution of solid Group III nitride in the solvent and to precipitate the single crystal Group III nitride crystals. More specifically, the process for making single crystal gallium nitride includes the steps of depositing a gallium nitride source, depositing a salt-based solvent, heating the solvent to render it molten and to provide a temperature gradient between the nitride source and the growing single crystal nitride and keeping the heat for a time to dissolve the nitride source to transfer the nitride through the layer of the solvent to create supersaturated solution of the nitride and to precipitate the nitride as a single crystal; and discontinuing the heating step.

The process involves the use of an alkali metal nitride alone or together with an alkali metal halide and/or an alkaline earth metal halide in a molten state as a solvent to promote dissolution therein of the solid nitride. Of the alkali nitrides, lithium nitride is preferred. Of the alkali metal halides, fluorides are preferred. Of special preference is the solvent lithium nitride, lithium fluoride and barium fluoride on about 1:1:1 weight basis. Generally, alkali metal nitrides with at least one alkali metal and/or alkaline earth metal fluorides and chlorides, are suitable as solvents in a molten state. Temperature difference inside the molten solvent between the nitride source and the growing single crystal nitride promotes dissolution of the nitride source, creating supersaturated solution of the nitride in the solvent and precipitation of the nitride either on the walls of the crucible containing the solvent and the source of the nitride or on one or more seed crystals disposed in a deposition zone.

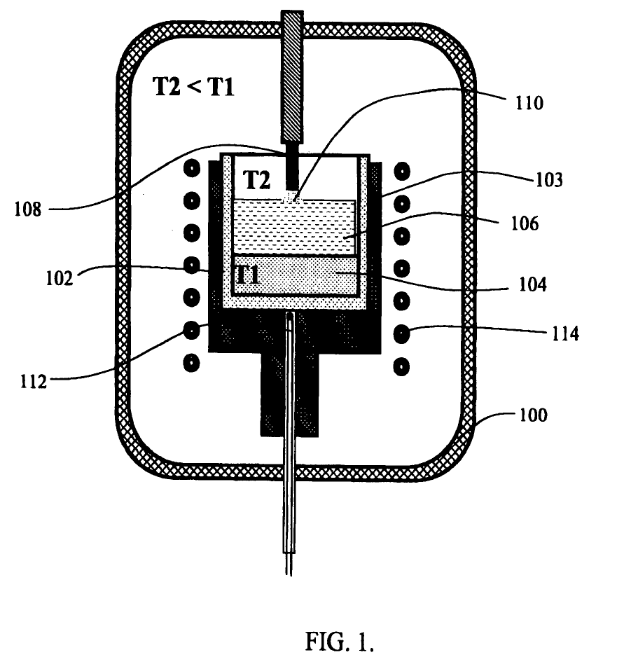

Disclosure of the process here is made in connection with the equipment shown in FIG. 1 where growth chamber 100 is shown containing within furnace 103 with crucible 102 disposed thereon containing the solid nitride 104, usually polycrystalline gallium nitride, as a source of the nitride 104, at bottom thereof and molten solvent 106 disposed thereover. Optional holder 108 holding optional seed nitride crystal 110 immersed in or in contact with solvent 106. Thermocouple 112 can measure temperature of the nitride 104 and coils 114 can heat the crucible 102 to the desired temperature in order to liquefy the solvent. Operation of the equipment shown in FIG. 1 typically involves disposition of the nitride 104 and the solvent 106 in the crucible 102, liquefying the solvent 106, providing a temperature difference whereby temperature of the solvent near the nitride source is higher than temperature of the molten solvent near the place where the single crystal nitride crystal(s) is growing, all under a nitrogen pressure in the chamber 100, precipitating the single crystal nitride and cooling the charge consisting of the source and the solvent.

During the process, the solvent is in a molten state at a temperature in the typical range of 700-900° C., more typically 750-850° C. and the nitrogen pressure in the growth chamber is typically above atmospheric, more typically 20-30 atmospheres. The solvent can be a eutectic in order to take advantage of lower temperatures. The temperature gradient, i.e., the temperature difference inside the solvent between the nitride source and the growing single crystal nitride, is typically 1-5° C./mm of solvent thickness, or typically 1-100° C. across the thickness of the solvent, and more typically 5-50° C.

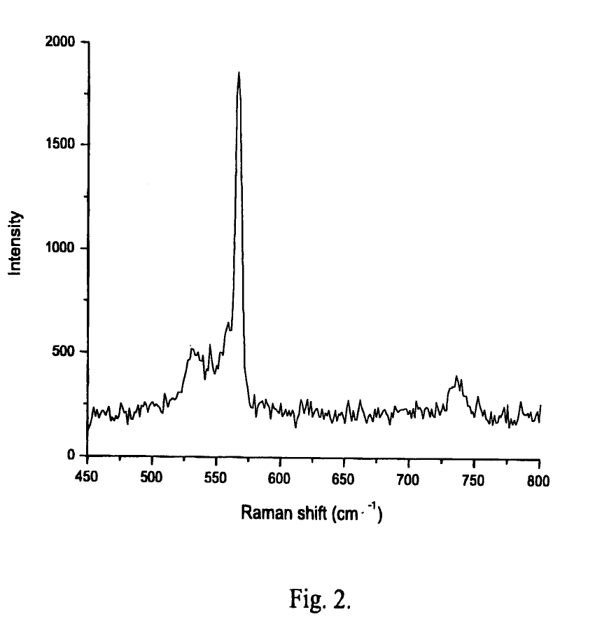

In an embodiment of this process with a seed crystal, the seed crystal is typically the coldest spot in the reactor when deposition of the single crystal nitride takes place. Due to the motive force imparted to the nitride dissolved in the solvent, the nitride leaves the solvent when the solvent becomes supersaturated with the nitride and deposits on the seed crystal and the seed crystal grows with accretion of teh nitride on its surface at a rate on the order of 500 microns per hour possibly in the r or the (1102) direction, as shown in FIG. 2, or in another crystallographic direction, but in excess of about 50 microns per hour. If the process is carried out without the seed crystal, then precipitation of the nitride will takes place on the colder parts of the crucible, i.e., vessel containing the solvent and the nitride source. The resulting crystal typically has single crystal structure, but may be polycrystalline.

Having described the invention, the following example is given as a particular embodiment thereof and to demonstrate the practice and advantages thereof. It is understood that the example is given by way of illustration and is not intended to limit the specification or the claims in any manner.

### EXAMPLE

This example demonstrates preparation of single crystal gallium nitride at a moderate temperature and moderate pressure using a salt-based solvent in the set-up shown in FIG. 1 where crucible 102, at about ¾ of an inch in diameter, contained sintered gallium nitride commercial powder 104 with the salt-based solvent 106 disposed thereover. All material preparations of the charge were carried out inside a glove box under a nitrogen atmosphere with moisture and oxygen content at under 1 ppm.

In carrying out the process, a layer of commercially available single crystal gallium nitride powder, which was preliminarily sintered and formed into a 1.2 g tablet of about ¼-inches in diameter and about ¼ inches thick, was placed at bottom of the crucible. The sintering procedure of the gallium nitride was at a pressure of 5-6 GPa and at a temperature of 1600-1700° C. for one hour. On top of the gallium nitride pill in the crucible was placed a mixture of 1.0 g lithium nitride (Li₃N), 1.3 g of lithium fluoride (LiF) and 1.3 g of barium fluoride (BaF₂). Although lithium nitride melts at about 840° C., lithium fluoride melts at about 850° C. and barium fluoride melts at about 1370° C., the above-mentioned mixture of the three components melted at about 760° C. The salt solvent was in the form of a solid chunk of the three components.

After the crucible was filled with the gallium nitride and the salt solvent, the crucible was placed into chamber 100. Initially, the chamber was evacuated to a vacuum level of 10⁻³ Torr, filled with nitrogen of 99.999999% purity to a pressure of 1 MPa (about 10 atmospheres) and then evacuated to a vacuum level of 10⁻³ Torr once more. After the evacuation, the furnace was filled with nitrogen of 99.9999% purity to a pressure of 2.5 MPa (about 25 atmospheres). Then the crucible was heated by heating coils 114 whereby temperature of the lower end of the crucible was 800° C. and temperature at the higher end of the solvent was 770° C., resulting in a temperature difference of 30° C. inside the solvent in the crucible. During heating, the solvent melted and gallium nitride started to dissolve thus saturating the solution, traveled through the solvent and precipitated on the interior colder parts of the crucible. These growth conditions of the process were maintained for one hour following which, the system was cooled to room temperature by turning off the heating coils and the nitrogen pressure was allowed to be reduced to atmospheric. The gallium nitride single crystals that had grown on the cold parts of the crucible were collected after dissolving the solvent in cold water.

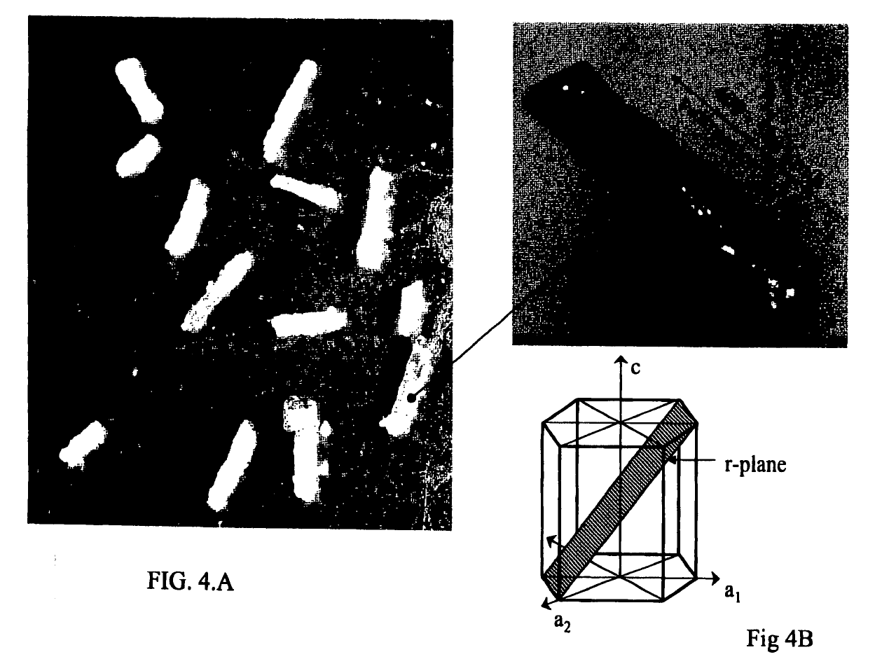

The gallium nitride crystals were about 0.5 mm long and 0.1 mm in diameter. The Raman spectrum of the crystals indicated that crystals were wurtzite type gallium nitride with good crystallinity, see FIGS. 4A and 4B. TEM measurements showed that the crystals to be single crystal gallium nitride with the growth axis in the r direction, see FIG. 2. The parallelogram shape of the top of the crystal is also evident from FIG. 2. Traces of gallium in the solvent were not found by examination under an optical microscope. The rod shape of the crystals differed from the hexagonal platelet growth reported for the sodium flux, the lithium flux and the high temperature and high pressure prior art techniques. The growth rate was 500 μm per our.

While presently preferred embodiments have been shown of the novel process, and of the several modifications discussed, persons skilled in this art will readily appreciate that various additional changes and modifications may be made without departing from the spirit of the invention as defined and differentiated by the following claims.

What is claimed is:

1. A process for making Group III nitride crystals comprising the steps of:
(a) charging a reaction vessel with a Group III nitride material source and a salt-based solvent in contact therewith;
(b) placing the charged reaction vessel into a chamber;
(c) heating the charge in the reaction vessel to render the solvent molten and to provide a temperature difference in the molten solvent between the nitride source and the growing single crystal nitride in such a way that growing the single crystal nitride will be in the region of the reaction vessel which, under operating conditions, has a temperature near the low end of the temperature difference and the nitride source will be in the region of the reaction vessel which, under operating conditions, has temperature near the high end of the temperature difference;
(d) maintaining process conditions whereby the solvent is molten, with the nitride from the nitride source dissolving in the solvent under the impetus of the temperature difference and precipitating out of the solvent; and
(e) discontinuing said heating step.

2. The process of claim 1 wherein said heating step is conducted in a nitrogen atmosphere exceeding one atmosphere.

3. The process of claim 2 wherein said heating step is carried out to a liquefaction temperature of the solvent.

4. The process of claim 3 wherein the temperature difference is on the order of 1-5° C./mm of solvent thickness.

5. The process of claim 3 wherein the temperature gradient is 1-100° C. across the solvent thickness.

6. The process of claim 1 wherein the solvent is selected from the group consisting of alkali metal nitrides combined with alkali metal halides, alkaline earth metal halides, and mixtures thereof.

7. The process of claim 5 wherein said heating step is conducted in a nitrogen atmosphere at a pressure on the order of 20-30 atmospheres.

8. The process of claim 7 including the step of disposing a Group III nitride seed crystal above the solvent whereby the nitride from the nitride source precipitates on the seed crystal.

9. The process of claim 8 wherein the solvent is selected from the group consisting of lithium nitride combined with alkali metal fluorides, alkaline earth metal fluorides, and mixtures thereof.

10. The process of claim 9 wherein the solvent is liquid at a temperature below 900° C.; the temperature difference is 5-50° C. across the solvent thickness; and accretion of the nitride from the nitride source is in excess of 300 μm/hr.

11. The process of claim 10 wherein the seed crystal is gallium nitride.

12. A process for growing single crystal gallium nitride comprising the steps of:
(a) charging a reaction vessel with gallium nitride material source and a salt-based solvent in contact therewith, the solvent is from the group consisting of alkali metals, alkali metal halides, alkaline metal halides, and mixtures thereof;
(b) placing the charged reaction vessel into a chamber;
(c) disposing gallium nitride seed crystal above the solvent;
(d) heating the charge in the reaction vessel to render the solvent molten and to provide a temperature gradient in the molten solvent between the gallium nitride source and the growing single crystal gallium nitride in such a way that growing the single crystal gallium nitride will be in the region of the reaction vessel which, under operating conditions, has a temperature near the low end of the temperature gradient and the gallium nitride source will be in the region of the reaction vessel which, under operating conditions, has a temperature near the high end of the temperature gradient;
(e) maintaining process conditions whereby the solvent is molten, with the gallium nitride from the gallium nitride source dissolving in the solvent under the impetus of the temperature gradient and precipitating out of the solvent; and
(f) discontinuing said heating step.

13. The process of claim 12 wherein temperature of the solvent is below 900° C. and wherein the alkali metals are alkali metal nitrides.

14. The process of claim 13 wherein the solvent temperature is in the range of 700-900° C. and wherein the nitrogen atmosphere is at a pressure above one atmosphere.

15. The process of claim 14 wherein the temperature gradient is on the order of 1-5° C./mm of solvent thickness.

16. The process of claim 14 wherein growth rate of the gallium nitride on the seed crystal is in excess of 300 μm/hr.

17. The process of claim 16 wherein the temperature gradient between the solvent and the gallium nitride disposed below the solvent is 5-50° C. across the solvent thickness.

18. The process of claim 17 wherein the nitrogen pressure above of the solvent is in the range of 20-30 atmospheres.

19. The process of claim 18 wherein accretion of the gallium nitride on the seed crystal is on the order 500 μm/hr.

20. The process of claim 19 for growing single crystal gallium nitride of at least one inch in dimension wherein the solvent is lithium nitride, lithium fluoride and barium fluoride in approximate 1:1:1 weight ratio.
